(19) United States
(12) Patent Application Publication
(10) Pub. No.: US 2026/0282308 A1
(43) Pub. Date: Sep. 17, 2026

(54) ELECTRONIC COMPONENT TRANSFER DEVICE AND HOLDER

(71) Applicant: Kioxia Corporation, Tokyo (JP)

(72) Inventors: Taishi NAKAHARA, Fujisawa Kanagawa (JP); Yuki TOSHINARI, Yokkaichi Mie (JP)

(73) Assignee: Kioxia Corporation, Tokyo (JP)

(21) Appl. No.: 19/314,009

(22) Filed: Aug. 29, 2025

(30) Foreign Application Priority Data
Mar. 12, 2025 (JP) 2025-039651

(51) Int. Cl. H05K 13/04; B65G 47/91

(52) U.S. Cl. CPC H05K 13/0409; B65G 47/91

(57) ABSTRACT

According to an embodiment, an electronic component transfer device includes a collet and a holder. The collet includes a suction surface having a quadrilateral shape with four right angles having a first side extending in a first direction and a second side extending in a second direction crossing the first direction in plan view and configured to hold an electronic component by sucking the electronic component, a first side surface arranged along the first direction and crossing the suction surface, and a second side surface arranged along the second direction and crossing the suction surface. The holder includes a first side wall in contact with the first side surface and having a first height and a second side wall in contact with the second side surface and having a second height lower than the first height and configured to hold the collet.

### CROSS REFERENCE TO RELATED APPLICATIONS

This application is based upon and claims the benefit of priority from the prior Japanese Patent Application No. 2025-39651, filed on Mar. 12, 2025, the entire contents of which are incorporated herein by reference.

### FIELD

The embodiments of the present invention relate to an electronic component transfer device and a holder.

### BACKGROUND

In a case of picking up an electronic component by using a transfer head provided with a suction collet, if a suction surface of the suction collet is bent, it may be difficult to appropriately pick up the electronic component.

### BRIEF DESCRIPTION OF THE DRAWINGS

FIG. 1 is a diagram illustrating an example of a configuration of a semiconductor manufacturing apparatus according to a first embodiment;

FIG. 2 is a front view illustrating an example of a configuration of a transfer head according to the first embodiment;

FIG. 3 is a left side view illustrating an example of the configuration of the transfer head according to the first embodiment;

FIG. 4 is a plan view illustrating an example of the configuration of the transfer head according to the first embodiment;

FIG. 5A is a diagram illustrating a manufacturing method of a semiconductor device according to the first embodiment;

FIG. 5B is a diagram illustrating the manufacturing method of a semiconductor device according to the first embodiment in continuation from FIG. 5A;

FIG. 5C is a diagram illustrating the manufacturing method of a semiconductor device according to the first embodiment in continuation from FIG. 5B;

FIG. 5D is a diagram illustrating the manufacturing method of a semiconductor device according to the first embodiment in continuation from FIG. 5C;

FIG. 5E is a diagram illustrating the manufacturing method of a semiconductor device according to the first embodiment in continuation from FIG. 5D;

FIG. 5F is a diagram illustrating the manufacturing method of a semiconductor device according to the first embodiment in continuation from FIG. 5E;

FIG. 5G is a diagram illustrating the manufacturing method of a semiconductor device according to the first embodiment in continuation from FIG. 5F;

FIG. 5H is a diagram illustrating the manufacturing method of a semiconductor device according to the first embodiment in continuation from FIG. 5G;

FIG. 5I is a diagram illustrating the manufacturing method of a semiconductor device according to the first embodiment in continuation from FIG. 5H;

FIG. 6 is a front view illustrating an example of a configuration of a transfer head according to a comparative example;

FIG. 7 is a diagram illustrating a manufacturing method of a semiconductor device according to the comparative example;

FIG. 8 is a diagram illustrating a bending amount of a suction surface of a suction collet in a transfer head according to a first working example of the first embodiment;

FIG. 9 is a diagram illustrating a bending amount of a suction surface of a suction collet in a transfer head according to a second working example of the first embodiment;

FIG. 10 is a diagram illustrating a bending amount of a suction surface of a suction collet in a transfer head according to the comparative example;

FIG. 11 is a front view illustrating a configuration of a transfer head according to a second embodiment;

FIG. 12 is a front view illustrating a configuration of a transfer head according to a third embodiment;

FIG. 13 is a plan view illustrating an example of a configuration of a transfer head according to a fourth embodiment;

FIG. 14 is a front view illustrating an example of a configuration of a transfer head according to a fifth embodiment;

FIG. 15 is a left side view illustrating an example of the configuration of the transfer head according to the fifth embodiment;

FIG. 16 is a plan view illustrating an example of the configuration of the transfer head according to the fifth embodiment;

FIG. 17 is a diagram illustrating a bending amount of a suction surface of a suction collet in a transfer head according to a working example of the fifth embodiment;

FIG. 18 is a front view illustrating an example of a configuration of a transfer head according to another comparative example; and

FIG. 19 is a diagram illustrating a bending amount of a suction surface of a suction collet in the transfer head according to the comparative example.

### DETAILED DESCRIPTION

According to an embodiment, an electronic component transfer device includes a collet and a holder. The collet includes a suction surface having a quadrilateral shape with four right angles having a first side extending in a first direction and a second side extending in a second direction crossing the first direction in plan view and configured to hold an electronic component by sucking the electronic component, a first side surface arranged along the first direction and crossing the suction surface, and a second side surface arranged along the second direction and crossing the suction surface. The holder includes a first side wall in contact with the first side surface and having a first height and a second side wall in contact with the second side surface and having a second height lower than the first height and configured to hold the collet.

Embodiments according to the present invention will now be explained below with reference to the drawings. The embodiments are not intended to limit the present invention. The drawings are schematic or conceptual and dimensional ratios of respective parts and the like are not always the same as those of actual products. In the specification and the drawings, elements identical to those described regarding the drawings already described are denoted by like reference characters and detailed descriptions thereof are omitted as appropriate.

### First Embodiment

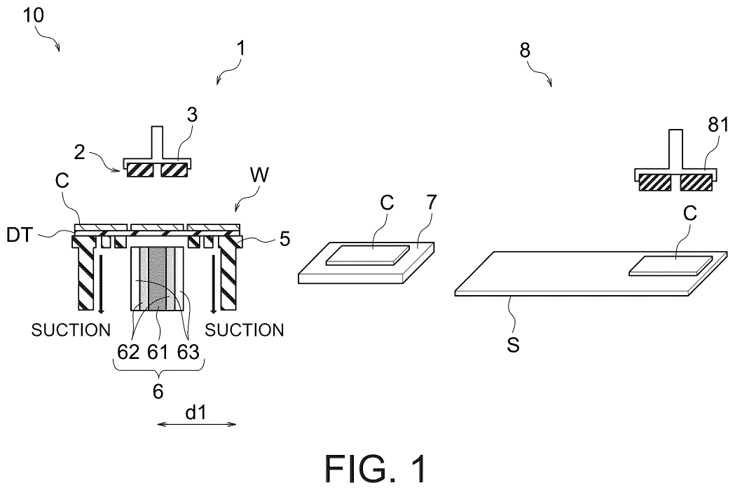

FIG. 1 is a diagram illustrating an example of a configuration of a semiconductor manufacturing apparatus according to a first embodiment. The semiconductor manufacturing apparatus includes a pickup device 10, a preciser 7, and a mounting device 8.

The pickup device 10 picks up a singulated electronic component from a dicing tape DT. The following descriptions are provided assuming that the electronic component is a semiconductor chip C. However, the electronic component is not limited to the semiconductor chip C.

The pickup device 10 includes a push-up mechanism 6, a wafer holder 5, and a transfer head 1. The push-up mechanism 6 is an example of a lifter. The wafer holder 5 is an example of an electronic component holder. The transfer head 1 is an example of an electronic component transfer device.

The push-up mechanism 6 can push up a plurality of semiconductor chips C singulated from a semiconductor wafer W. For example, the semiconductor chip C has a quadrilateral shape with four right angles as viewed in a direction substantially perpendicular to the semiconductor wafer W. The push-up mechanism 6 is caused to move to a position below the semiconductor chip C to be picked up. The push-up mechanism 6 pushes up the semiconductor chip C and the dicing tape DT from below. The push-up mechanism 6 may have a multiple-stage push-up configuration in which a plurality of push-up members can be raised and lowered independently of each other. In the example illustrated in FIG. 1, the push-up mechanism 6 includes a first push-up member 61 at the center, a second push-up member 62 arranged outside the first push-up member 61 to be adjacent thereto, and a third push-up member 63 arranged outside the second push-up member 62 to be adjacent thereto. The first to third push-up members 61 to 63 can be raised and lowered independently of each other. The second push-up member 62 may be arranged around the first push-up member 61 as a single configuration to surround the entire circumference of the first push-up member 61. Alternatively, the second push-up member 62 may be arranged as a configuration divided in the right-left direction (a direction d1 in FIG. 1). In a case of dividing the second push-up member 62 in the right-left direction, the divided second push-up members 62 can be raised and lowered independently of each other. Further, the third push-up member 63 may be arranged around the second push-up member 62 as a single configuration to surround the entire circumference of the second push-up member 62. Alternatively, the third push-up member 63 may be arranged as a configuration divided in the right-left direction. In a case of dividing the third push-up member 63 in the right-left direction, the divided third push-up members 63 can be raised and lowered independently of each other.

The wafer holder 5 is arranged around the push-up mechanism 6. The wafer holder 5 holds the semiconductor chips C around the semiconductor chip C pushed up by the push-up mechanism 6. The wafer holder 5 has a suction hole for sucking the back surface of the dicing tape DT. The wafer holder 5 is connected to a vacuum pump (not illustrated). The wafer holder 5 holds, by suction, the semiconductor chips C around the semiconductor chip C that is to be pushed up.

The transfer head 1 picks up and transfers the semiconductor chip C pushed up by the push-up mechanism 6. The transfer head 1 includes a suction collet 2 that holds the semiconductor chip C by sucking it and a collet holder 3 that holds the suction collet 2. For example, the transfer head 1 transfers a single semiconductor chip C at a time. The transfer head 1 may transfer a plurality of the semiconductor chips C collectively at a time. Further details of the transfer head 1 are described later.

The preciser 7 holds the semiconductor chip C transferred by the transfer head 1. For example, the preciser 7 holds the semiconductor chip C by suction. Since the preciser 7 is included, it is possible to perform an operation of picking up the semiconductor chip C and a mounting operation independently of each other. Accordingly, the processing time required for picking up and mounting semiconductor chips can be shortened.

The preciser 7 can switch a state of holding the semiconductor chip C and a state of not holding the semiconductor chip C. The preciser 7 includes a plurality of suction portions (not illustrated) each capable of sucking the semiconductor chip C. Each suction portion (for example, a suction hole) is connected to a vacuum pump (not illustrated).

The mounting device 8 places the semiconductor chip C on an object on which mounting is to be performed. The following descriptions are provided assuming that the object on which mounting is to be performed is a wiring substrate S. However, the object on which mounting is to be performed is not limited to the wiring substrate S.

The mounting device 8 includes a mounting head 81.

The mounting head 81 sucks the semiconductor chip C held by the preciser 7 and mounts the sucked semiconductor chip C on the wiring substrate S. Similarly to the transfer head 1, the mounting head 81 includes a suction collet and a collet holder, for example.

Next, a detailed configuration of the transfer head 1 is described.

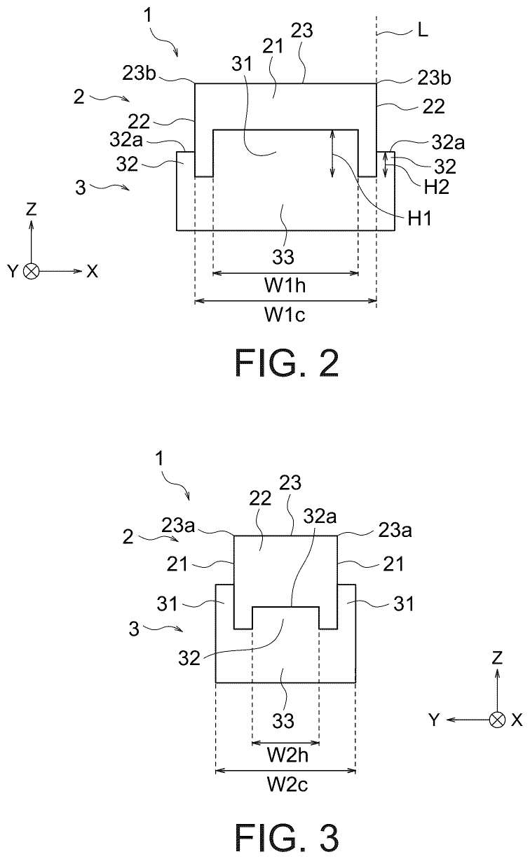

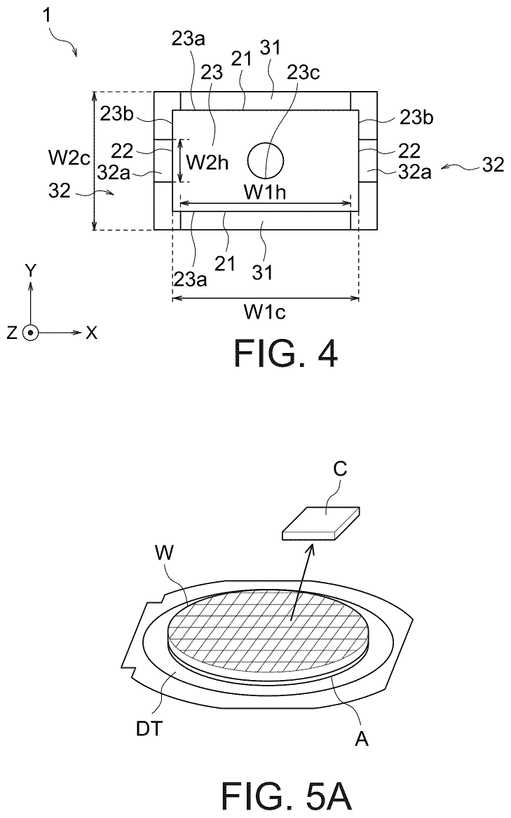

FIG. 2 is a front view illustrating an example of a configuration of the transfer head 1 according to the first embodiment. FIG. 3 is a left side view illustrating an example of the configuration of the transfer head 1 according to the first embodiment. FIG. 4 is a plan view illustrating an example of the configuration of the transfer head 1 according to the first embodiment.

As illustrated in FIGS. 2 to 4, the transfer head 1 includes the suction collet 2 and the collet holder 3 described above. The suction collet 2 is an example of a collet. The collet holder 3 is an example of a holder.

As illustrated in FIG. 4, in plan view, the suction collet 2 includes a suction surface 23 in a quadrilateral shape with four right angles having a pair of first sides 23a extending in the X-direction as an example of a first direction and a pair of second sides 23b extending in the Y-direction as an example of a second direction. The suction surface 23 holds the semiconductor chip C by sucking it. In the example illustrated in FIG. 4, the suction surface 23 having a rectangular shape in which the first sides 23a are long sides and the second sides 23b are short sides. That is, in the example illustrated in FIG. 4, the suction surface 23 has a rectangular shape whose longitudinal direction is the X-direction. The suction collet 2 further includes a first side surface 21 and a second side surface 22. The suction collet 2 is made of resin, for example.

The first side surface 21 is provided along the X-direction to cross the suction surface 23 (that is, cross it at right angles). In other words, the first side surface 21 is provided to cross the Y-direction the suction surface 23. In the example illustrated in FIG. 4, the first side surface 21 is connected to the suction surface 23 on one first side 23a. In the example illustrated in FIG. 3, one of the first sides 23a corresponds to the upper end of the first side surface 21. In more detail, when the direction crossing the X- and Y-directions at right angles is defined as the Z-direction, the first side surface 21 is provided along the X-Z plane. The Z-direction is an example of a third direction. A pair of the first side surfaces 21 is provided to be spaced apart from each other in the Y-direction.

The second side surface 22 is provided along the Y-direction to cross the suction surface 23. In other words, the second side surface 22 is provided to cross the X-direction the suction surface 23. In the example illustrated in FIG. 4, the second side surface 22 is connected to the suction surface 23 on one second side 23b. In the example illustrated in FIG. 2, one of the second sides 23b corresponds to the upper end of the second side surface 22. In more detail, the second side surface 22 is provided along the Y-Z plane. A pair of the second side surfaces 22 is provided to be spaced apart from each other in the X-direction. An end of the second side surface 22 in the Y-direction is connected to an end of the first side surface 21 in the X-direction.

The suction surface 23 is provided to cross the first side surface 21 and the second side surface 22. The suction surface 23 is provided with an air inlet 23c that sucks air.

The suction surface 23 is a flat surface crossing the first side surfaces 21 and the second side surfaces 22. The flat surface is not limited to a flat surface in a strict sense with no variation in height, but includes a substantially flat surface in which the variation in height is sufficiently suppressed. If the suction surface 23 is bent, a gap is generated at a certain location between the suction collet 2 and the collet holder 3 because the volume of the suction collet 2 is unchanged. This generation of gap causes suction leakage of the semiconductor chip C. Meanwhile, in the first embodiment, the suction surface 23 is a flat surface. Therefore, as compared with a case where the suction surface 23 is bent, it is possible to suppress generation of gap between the suction collet 2 and the collet holder 3. Since generation of gap can be suppressed, suction leakage of the semiconductor chip C can be reduced.

In a state where the suction collet 2 is held by the collet holder 3, the variation in height of the suction surface 23 may be 70 μm or less. The variation in height can be also said to be the maximum value of a deviation of the height of the suction surface 23 from a reference height of the suction surface 23 when the bending amount of the suction surface 23 is zero. The variation in height can be also said to be the maximum bending amount of the suction surface 23. Since the variation in height of the suction surface 23 is 70 μm or less, bending of the suction surface 23 can be suppressed. By suppressing bending of the suction surface 23, suction leakage of the semiconductor chip C can be reduced.

The variation in height of the suction surface 23 may be 55 μm or less. Since the variation in height of the suction surface 23 is 55 μm or less, bending of the suction surface 23 can be further suppressed. By further suppressing bending of the suction surface 23, suction leakage of the semiconductor chip C can be further reduced.

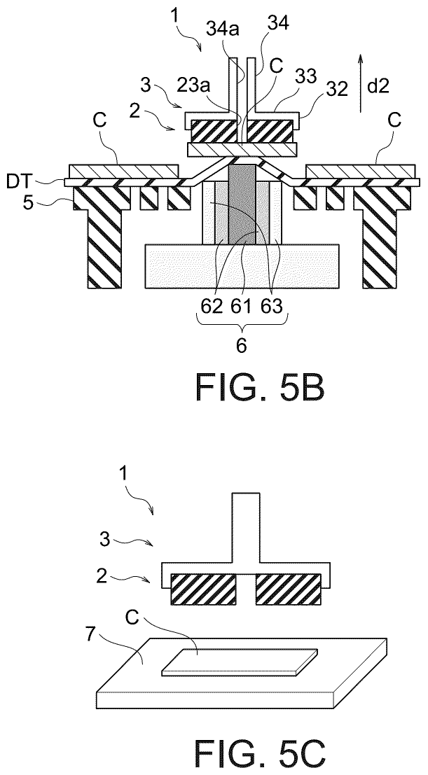

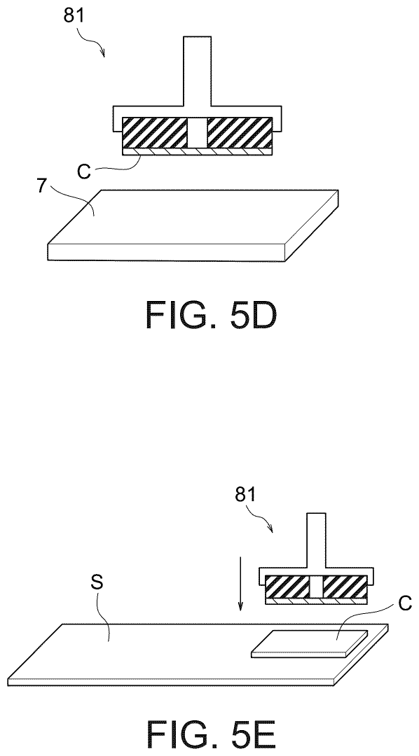

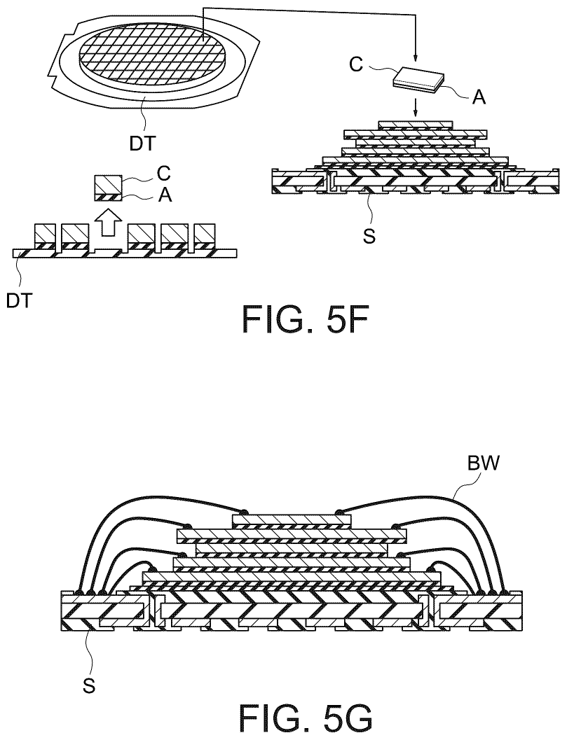

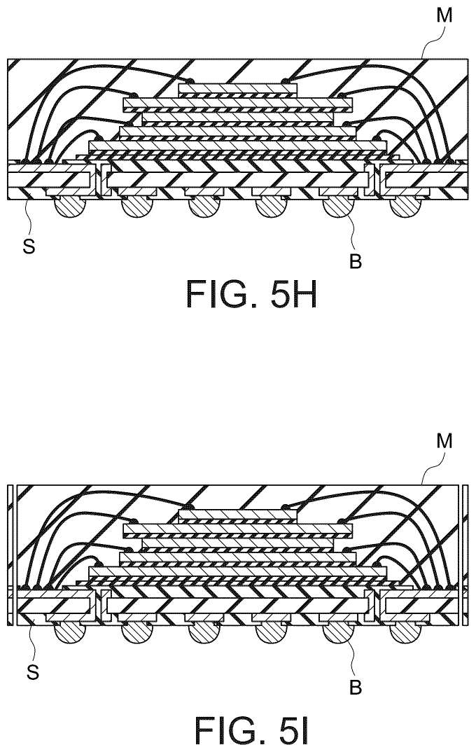

The collet holder 3 includes a first side wall 31 along the X-direction, a second side wall 32 along the Y-direction, and a base 33. As illustrated in FIG. 5B, the collet holder 3 further includes a cylindrical portion 34 connected to the base 33. Inside the cylindrical portion 34, a ventilation path 34a (that is, an exhaust path) communicating with the air inlet 23c of the suction collet 2 is provided. The cylindrical portion 34 is connected to a vacuum pump (not illustrated) at an end on the opposite side of the suction collet 2.

The base 33 has a rectangular shape extending in the X-direction in plan view. The base 33 has a predetermined thickness in the Z-direction.

A pair of the first side walls 31 is provided to extend upward (that is, in the Z-direction) from the respective end edges in the Y-direction of the upper surface of the base 33. The first side walls 31 are in contact with the first side surfaces 21 of the suction collet 2, respectively. In the Z-direction, the position of the lower ends of the first side walls 31 in contact with the upper surface of the base 33 is the same as the position of the lower ends of the second side walls 32 in contact with the upper surface of the base 33. Each of the first side walls 31 has a first width W1h in the X-direction. Each of the first side walls 31 has a first height H1 lower than the height of the suction surface 23 with respect to the lower ends of the first side walls 31 (that is, the lower ends of the second side walls 32) as a reference. That is, the distance H1 from the lower end of each first side wall 31 to the upper end of that first side wall 31 is shorter than the distance from the lower end of each first side wall 31 to the suction surface 23.

A pair of the second side walls 32 is provided to extend upward (that is, in the Z-direction) from the respective end edges in the X-direction of the upper surface of the base 33. The second side walls 32 are in contact with the second side surfaces 22 of the suction collet 2, respectively. Each of the second side walls 32 has a second width W2h smaller than the first width W1h in the Y-direction. Each of the second side walls 32 has a second height H2 lower than the first height H1. That is, the distance H2 from the lower end of each second side wall 32 to the upper end of that second side wall 32 is shorter than the distance H1 from the lower end of each first side wall 31 to the upper end of that first side wall 31.

The collet holder 3 holds the suction collet 2 in a space surrounded by the upper surface of the base 33, the pair of first side walls 31, and the pair of second side walls 32. The suction collet 2 is held by the collet holder 3 by being fitted into the collet holder 3. Since the height of the second side walls 32 is lower than the height of the first side walls 31, bending of the suction surface 23 caused by fitting of the suction collet 2 into the collet holder 3 can be suppressed. By suppressing bending of the suction surface 23, suction leakage of the semiconductor chip C can be reduced appropriately.

As indicated with a broken line L in FIG. 2, it is not necessary that at least an upper-end side portion of each second side surface 22 of the suction collet 2, which is adjacent to the suction surface 23, protrudes outward from the inner surface of the corresponding second side wall 32. That is, as viewed in the Y-direction, at least the upper-end side portion of each second side surface 22 may be positioned between the end of the first side wall 31 in the X-direction and the inner surface of the corresponding second side wall 32. Since the upper-end side portion of the second side surface 22 does not protrude from the inner surface of the corresponding second side wall 32, bending of the suction surface 23 can be suppressed more effectively.

The second side surfaces 22 of the suction collet 2 may be flat surfaces along the inner surfaces of the second side walls 32 of the collet holder 3. Since the second side surfaces 22 are flat surfaces, bending of the suction surface 23 can be suppressed more effectively.

In the collet holder 3, the second height H2 of the second side walls 32 may be equal to or less than ½ of the first height of the first side walls 31. Since the second height H2 is equal to or less than ½ of the first height, the variation in height of the suction surface 23 can be suppressed. For example, the variation in height of the suction surface 23 can be suppressed to 70 μm or less. Accordingly, bending of the suction surface 23 can be suppressed more appropriately.

The second height H2 may be equal to or less than ⅓ of the first height H1. Since the second height H2 is equal to or less than ⅓ of the first height, the variation in height of the suction surface 23 can be suppressed further. For example, the variation in height of the suction surface 23 can be suppressed to 55 μm or less. Accordingly, bending of the suction surface 23 can be suppressed more appropriately.

In the example illustrated in FIG. 2, an upper end surface 32a of each second side wall 32 is a horizontal surface parallel to the X-Y plane. The second side walls 32 have the second height H2 in its entirety.

In the example illustrated in FIGS. 2 to 4, in the X-direction, the first width W1h of each first side wall 31 of the collet holder 3 is shorter than a width W1c of each first side surface 21 of the suction collet 2. Further, in the Y-direction, the second width W2h of each second side wall 32 of the collet holder 3 is shorter than a width W2c of each second side surface 22 of the suction collet 2. Since the first width W1h of each first side wall 31 is shorter than the width W1c of each first side surface 21 and the second width W2h of each second side wall 32 is shorter than the width W2c of each second side surface 22, it is possible to easily fit the suction collet 2 into the collet holder 3.

The configuration of the collet holder 3 of the transfer head 1 can be also applied to a collet holder of the mounting head 81.

Next, a manufacturing method of a semiconductor device using the semiconductor manufacturing apparatus having the configuration described above is described.

FIG. 5A is a diagram illustrating a manufacturing method of a semiconductor device according to the first embodiment. First, as illustrated in FIG. 5A, the semiconductor wafer W is singulated into the semiconductor chips C. The semiconductor wafer W is singulated while being bonded to the dicing tape DT via an adhesive layer A.

FIG. 5B is a diagram illustrating the manufacturing method of a semiconductor device according to the first embodiment in continuation from FIG. 5A. After the semiconductor wafer W is singulated, the wafer holder 5 holds the semiconductor chips C around the semiconductor chip C to be pushed up. Holding the semiconductor chips C is performed by suction by the wafer holder 5.

As illustrated in FIG. 5B, after the semiconductor chips C around the semiconductor chip C to be pushed up are held, the semiconductor chip C to be pushed up is pushed up by the push-up mechanism 6. A direction d2 in FIG. 5B indicates the direction in which the semiconductor chip C is pushed up by the push-up mechanism 6.

At this time, the transfer head 1 picks up the semiconductor chip C by sucking it onto the suction surface 23 of the suction collet 2 via the ventilation path 34a and the air inlet 23c by a vacuum pump (not illustrated). Further, at this time, since bending of the suction surface 23 of the suction collet 2 is suppressed, the semiconductor chip C can be picked up appropriately with suction leakage being suppressed.

In the example illustrated in FIG. 5B, the dicing tape DT around the first push-up member 61 is separated from the semiconductor chip C because the first push-up member 61 is raised. The operation of separating the dicing tape DT from the semiconductor chip C may be performed in a stepwise manner. For example, the upper end of the first push-up member 61 and the upper end of the second push-up member 62 may be raised to the same height as each other to cause separation of the dicing tape DT around the second push-up member 62, and thereafter the upper end of the first push-up member 61 may be further raised to cause separation of the dicing tape DT around the first push-up member 61. Other than the above procedure, the push-up mechanism 6 can perform a desired operation that can be achieved by raising and lowering the first to third push-up members 61 to 63 independently of each other.

FIG. 5C is a diagram illustrating the manufacturing method of a semiconductor device according to the first embodiment in continuation from FIG. 5B. As illustrated in FIG. 5C, after the semiconductor chip C is picked up, the semiconductor chip C is transferred by the transfer head 1 onto the preciser 7. In FIG. 5C, the ventilation path 34a is not illustrated.

FIG. 5D is a diagram illustrating the manufacturing method of a semiconductor device according to the first embodiment in continuation from FIG. 5C. As illustrated in FIG. 5D, after the semiconductor chip C is transferred, the semiconductor chip C is sucked by the mounting head 81. Further, suction (holding) of the semiconductor chip C sucked by the mounting head 81 is stopped by the preciser 7.

FIG. 5E is a diagram illustrating the manufacturing method of a semiconductor device according to the first embodiment in continuation from FIG. 5D. As illustrated in FIG. 5E, after the semiconductor chip C is sucked by the mounting head 81, the semiconductor chip C is mounted on the wiring substrate S.

FIG. 5F is a diagram illustrating the manufacturing method of a semiconductor device according to the first embodiment in continuation from FIG. 5E. As illustrated in FIG. 5F, by repeating the steps in FIGS. 5A to 5E for the semiconductor chips C that are different in size and type in turn, singulated semiconductor chips C are mounted on the wiring substrate S. In the example illustrated in FIG. 5F, the semiconductor chips C are mounted on the wiring substrate S to be stacked in a direction substantially perpendicular to the wiring substrate S.

FIG. 5G is a diagram illustrating the manufacturing method of a semiconductor device according to the first embodiment in continuation from FIG. 5F. As illustrated in FIG. 5G, after the semiconductor chips C are mounted, bonding wires BW electrically connecting the wiring substrate S and the semiconductor chips C to each other are formed.

FIG. 5H is a diagram illustrating the manufacturing method of a semiconductor device according to the first embodiment in continuation from FIG. 5G. As illustrated in FIG. 5H, after the bonding wires BW are formed, mold resin M covering the semiconductor chips C and the bonding wires BW is formed on the wiring substrate S. Further, a metal bump B is formed on the lower surface of the wiring substrate S. The metal bump B is a solder ball, for example.

FIG. 5I is a diagram illustrating the manufacturing method of a semiconductor device according to the first embodiment in continuation from FIG. 5H. As illustrated in FIG. 5I, after the mold resin M and the metal bump B are formed, a semiconductor package is singulated. With this process, the semiconductor device is completed.

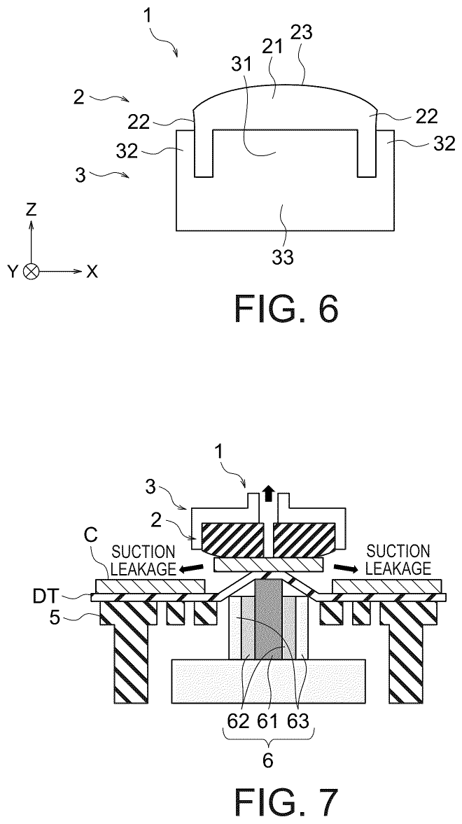

FIG. 6 is a front view illustrating an example of a configuration of the transfer head 1 according to a comparative example. FIG. 7 is a diagram illustrating a manufacturing method of a semiconductor device according to the comparative example. When the height of the second side walls 32 is the same as the height of the first side walls 31 in the collet holder 3, the force of pushing the suction collet 2 by the second side walls 32 becomes large according to procedures of fitting the suction collet 2 into the collet holder 3.

Specifically, in a case of inserting four corners of the suction collet 2 into the collet holder 3 prior to the central portion of the suction collet 2, the force of pushing the suction collet 2 by the second side walls 32 becomes large. Since the force of pushing the suction collet 2 by the second side walls 32 becomes large, a reaction force of pushing back the second side walls 32 by the second side surfaces 22 of the suction collet 2 becomes large.

As illustrated in FIG. 6, since the reaction force applied by the suction collet 2 becomes large, bending of the suction surface 23 in a convex shape becomes large. As illustrated in FIG. 7, since bending of the suction surface 23 becomes large, suction leakage occurs when the semiconductor chip C is picked up.

Meanwhile, according to the first embodiment, the height of the second side walls 32 is lower than the height of the first side walls 31 in the collet holder 3 as described above. Since the height of the second side walls 32 is lower, the force of pushing the suction collet 2 by the second side walls 32 can be reduced.

Due to reduction of the force of pushing the suction collet 2 by the second side walls 32, the reaction force of pushing back the second side walls 32 by the second side surfaces 22 of the suction collet 2 can be reduced. As illustrated in FIG. 2, due to reduction of the reaction force applied by the suction collet 2, bending of the suction surface 23 can be suppressed. By suppressing bending of the suction surface 23, suction leakage can be suppressed when the semiconductor chip C is picked up.

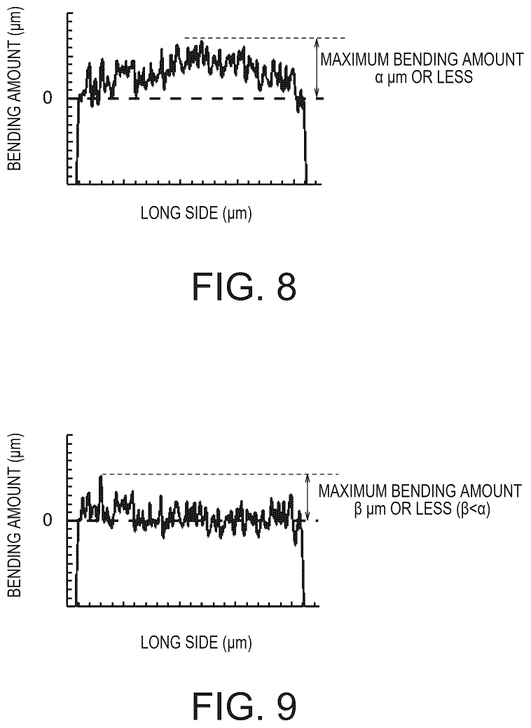

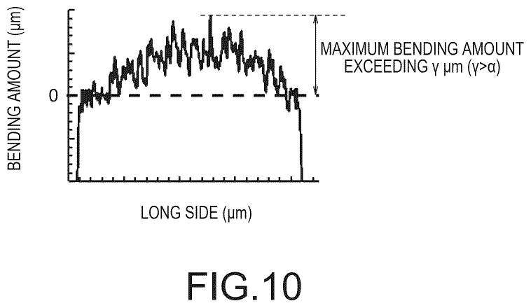

Next, working examples of the transfer head 1 according to the first embodiment are described. FIG. 8 is a diagram illustrating a measurement result of the bending amount of the suction surface 23 of the suction collet 2 in the transfer head 1 according to a first working example of the first embodiment. FIG. 9 is a diagram illustrating a measurement result of the bending amount of the suction surface 23 of the suction collet 2 in the transfer head 1 according to a second working example of the first embodiment. FIG. 10 is a diagram illustrating a measurement result of the bending amount of the suction surface 23 of the suction collet 2 in the transfer head 1 according to the comparative example. In the examples illustrated in FIGS. 8 to 10, the suction surface 23 has a rectangular shape whose longitudinal direction is the X-direction (see FIG. 4).

In the first working example illustrated in FIG. 8, the second height H2 of the second side walls 32 is ½ of the first height H1 of the first side walls 31.

The horizontal axis in FIG. 8 represents a position in the X-direction (that is, the longitudinal direction) of the suction collet 2 with respect to one end of the suction collet 2 in the X-direction as a reference. The vertical axis in FIG. 8 represents the bending amount of the suction surface 23 corresponding to a position in the X-direction of the suction collet 2. In the first working example illustrated in FIG. 8, the bending amount is defined as a deviation of the height of the suction surface 23 from the reference height 0 (μm) of the suction surface 23 when the suction surface 23 is not bent.

As illustrated in FIG. 8, in a case of setting the height of the second side walls 32 to ½ of the height of the first side walls 31, the maximum bending amount that is the maximum value of the height of the suction surface 23 can be suppressed to α μm or less.

In the second working example illustrated in FIG. 9, the second height H2 of the second side walls 32 is ¼ of the first height H1 of the first side walls 31. Other conditions and definitions of terms in FIG. 9 are the same as those in FIG. 8.

As illustrated in FIG. 9, in a case of setting the height of the second side walls 32 to ¼ of the height of the first side walls 31, the maximum bending amount of the suction surface 23 can be suppressed to β μm or less (where β<α).

In the comparative example illustrated in FIG. 10, the height of the second side walls 32 is the same as the height of the first side walls 31. Other conditions and definitions of terms in FIG. 10 are the same as those in FIG. 8.

As illustrated in FIG. 10, in a case where the height of the second side walls 32 is the same as the height of the first side walls 31, the maximum bending amount of the suction surface 23 exceeds γ μm (where γ>α).

From the measurement results in FIGS. 8 to 10, it is confirmed that the suction surface 23 is closer to a planar shape from a convex shape in the case of FIG. 8 than in the case of FIG. 10, or in the case of FIG. 9 than in the case of FIG. 9. That is, the measurement results in FIGS. 8 to 10 revealed that bending of the suction surface 23 can be suppressed by making the height of the second side walls 32 lower than the height of the first side walls 31. In more detail, it is confirmed that by setting the height of the second side walls 32 to ½ of the height of the first side walls 31, the variation in the height of the suction surface 23 can be suppressed than in the case of setting the height of the second side walls 32 to the same height as the height of the first side walls 31. Further, it is confirmed that by setting the height of the second side walls 32 to ¼ of the height of the first side walls 31, the variation in the height of the suction surface 23 can be further suppressed than in the case of setting the height of the second side walls 32 to ½ of the height of the first side walls 31.

As described above, according to the first embodiment, it is possible to suppress bending of the suction surface 23 by making the second height H2 of each second side wall 32 lower than the first height H1 of each first side wall 31 in the collet holder 3. Accordingly, the semiconductor chip C can be picked up appropriately with suction leakage of the semiconductor chip C suppressed.

### Second Embodiment

Next, a second embodiment in which the upper end surface 32a of each second side wall 32 is an inclined surface is described, focusing on differences from the embodiment described above.

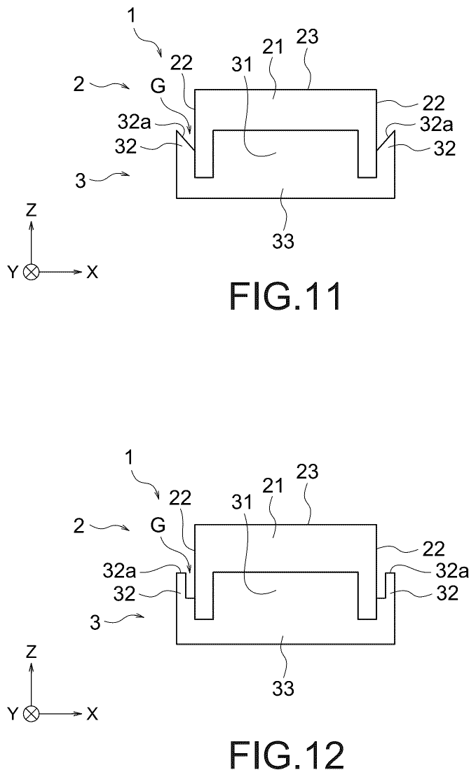

FIG. 11 is a front view illustrating a configuration of the transfer head 1 according to the second embodiment. The above descriptions have been provided as to an example of the transfer head 1 in which the upper end surface 32a of each second side wall 32 is a horizontal surface. Meanwhile, in the second embodiment, the upper end surface 32a of each second side wall 32 is an inclined surface. The second side walls 32 partly have the second height lower than the first height of the first side walls 31.

In the example illustrated in FIG. 11, the inclined surface constituting the upper end surface 32a of each second side wall 32 is inclined in such a manner that the height thereof decreases toward the second side surface 22 of the suction collet 2. In the example illustrated in FIG. 11, the height of the uppermost portion of the upper end surface 32a of each second side wall 32, which is positioned at the outermost position in the upper end surface 32a, is the same as the height of the first side walls 31. The height of the upper end surface 32a other than the uppermost portion is lower than the height of the first side walls 31. The height of the short-side wall of each second side wall 32 that is in contact with the corresponding second side surface 22 of the suction collet 2 (that is, the inner end of the upper end surface 32a) may be the same as the second height H2 of each second side wall 32 illustrated in the first embodiment. In a case where the upper end surface 32a is inclined or stepped as described later, a gap G is formed between the long-side wall of the second side wall 32 that is the farthest from the corresponding second side surface 22 (that is, the outer end of the upper end surface 32a) and the corresponding second side surface 22. The gap G allows the lower-end side portion of the suction collet 2 to be pushed and enter thereinto when the suction collet 2 is fitted into the collet holder 3. Since the lower-end side portion of the suction collet 2 is pushed and enters, deformation of the suction surface 23 at the upper end of the suction collet 2 can be absorbed. Accordingly, bending of the suction surface 23 can be suppressed more effectively.

According to the second embodiment, by making the upper end surface 32a of each second side wall 32 inclined, it is possible to make the height of the second side walls 32 partly lower than the first height of the first side walls 31. Consequently, similarly to the first embodiment, the force of pushing the suction collet 2 by the second side walls 32 and a reaction force of pushing back the second side walls 32 by the second side surfaces 22 can be reduced, so that bending of the suction surface 23 can be suppressed. Therefore, also in the second embodiment, suction leakage can be suppressed when the semiconductor chip C is picked up.

In addition, according to the second embodiment, the opening for fitting the suction collet 2 can be widened by the upper end surface 32a being inclined. Accordingly, it is possible to make it easy to attach the suction collet 2 to the collet holder 3 while suppressing bending of the suction surface 23.

### Third Embodiment

Next, a third embodiment in which the upper end surface 32a of each second side wall 32 is a stepped surface is described, focusing on differences from the embodiments described above.

FIG. 12 is a front view illustrating a configuration of the transfer head 1 according to the third embodiment. In the third embodiment, the upper end surface 32a of each second side wall 32 is a stepped surface. The second side walls 32 partly have the second height lower than the first height of the first side walls 31.

In the example illustrated in FIG. 12, the stepped surface constituting the upper end surface 32a of each second side wall 32 has a step that makes the height on the second side surface 22 side lower. In the example illustrated in FIG. 12, the height of an outer portion in the upper end surface 32a is the same as the height of the first side walls 31. Further, the height of an inner portion in the upper end surface 32a is lower than the height of the first side walls 31.

According to the third embodiment, by forming the upper end surface 32a of each second side wall 32 by a stepped surface, it is possible to make the height of the second side walls 32 partly lower than the first height of the first side walls 31. Consequently, similarly to the first embodiment, the force of pushing the suction collet 2 by the second side walls 32 and a reaction force of pushing back the second side walls 32 by the second side surfaces 22 can be reduced, so that bending of the suction surface 23 can be suppressed. Therefore, also in the third embodiment, suction leakage can be suppressed when the semiconductor chip C is picked up.

In addition, according to the third embodiment, the opening for fitting the suction collet 2 can be widened by the upper end surface 32a formed by the stepped surface. Accordingly, it is possible to make it easy to attach the suction collet 2 to the collet holder 3 while suppressing bending of the suction surface 23.

### Fourth Embodiment

Next, a fourth embodiment in which the suction surface 23 of the suction collet 2 has a square shape is described, focusing on differences from the embodiments described above.

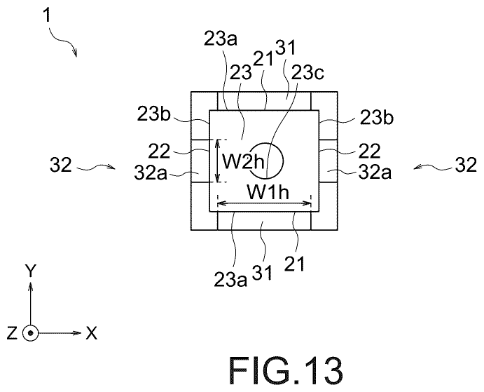

FIG. 13 is a plan view illustrating an example of a configuration of the transfer head 1 according to the fourth embodiment. The above descriptions have been provided as to an example of the suction collet 2 in which the suction surface 23 has a rectangular shape. Meanwhile, in the fourth embodiment, the suction surface 23 of the suction collet 2 has a square shape. That is, in the fourth embodiment, the length of each first side 23a and the length of each second side 23b are the same as each other. In other words, the dimension in the X-direction of each first side surface 21 is the same as the dimension in the Y-direction of each second side surface 22. Further, the dimension in the X-direction of each first side wall 31 is the same as the dimension in the Y-direction of each second side wall 32. Other configurations of the fourth embodiment are identical to those of the first embodiment. For example, also in the fourth embodiment, similarly to FIG. 2, the second height H2 of each second side wall 32 is lower than the first height H1 of each first side wall 31. Further, in the example illustrated in FIG. 13, the second width W2h of each second side wall 32 is smaller than the first width W1h of each first side wall 31.

Also in the fourth embodiment, it is possible to suppress bending of the suction surface 23 by making the second height H2 of each second side wall 32 lower than the first height H1 of each first side wall 31. Further, the flexibility of the shape of the suction collet 2 can be increased.

### Fifth Embodiment

Next, a fifth embodiment in which the collet holder 3 does not have the side walls 32 is described, focusing on differences from the embodiments described above.

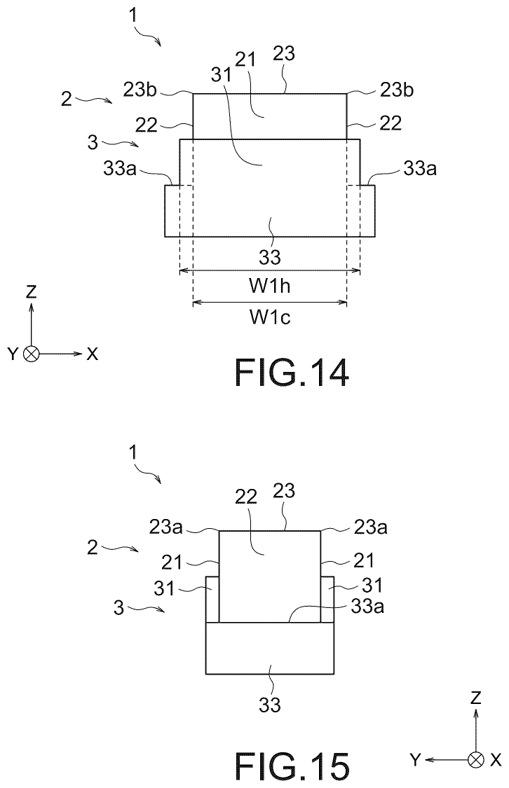

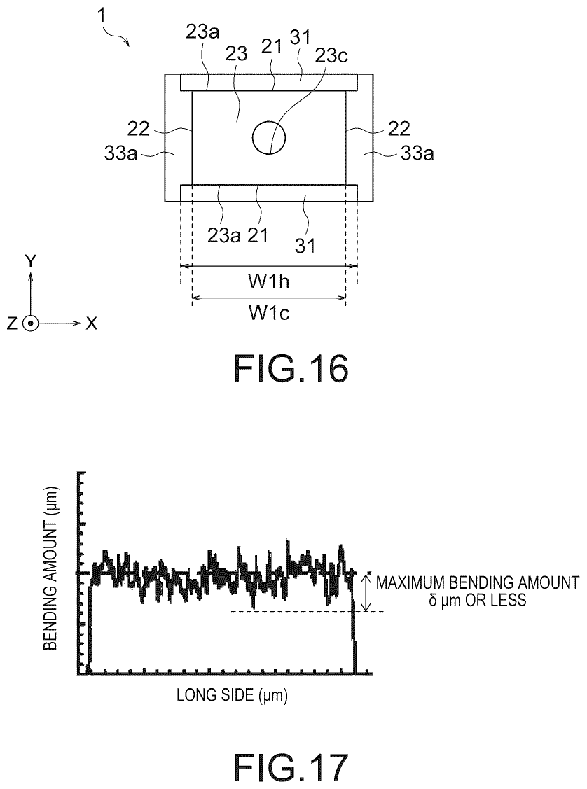

FIG. 14 is a front view illustrating an example of a configuration of the transfer head 1 according to the fifth embodiment. FIG. 15 is a left side view illustrating an example of the configuration of the transfer head 1 according to the fifth embodiment. FIG. 16 is a plan view illustrating an example of the configuration of the transfer head 1 according to the fifth embodiment.

As illustrated in FIGS. 14 to 16, the collet holder 3 according to the fifth embodiment has the first side walls 31 but does not have the second side walls 32. In other words, the collet holder 3 includes a flat-surface portion 33a adjacent to the second side surface 22 of the suction collet 2. The position of the flat-surface portion 33a in the Z-direction is the same as the position of the lower end of each first side wall 31 in the Z-direction.

In the X-direction, the width W1h of each first side wall 31 is equal to or larger than the width W1c of each first side surface 21. Since the width W1h of each first side wall 31 is equal to or larger than the width W1c of each first side surface 21, each first side wall 31 can be in contact with both ends in the X-direction of the corresponding first side surface 21 of the suction collet 2. Since each first side wall 31 is in contact with the both ends in the X-direction of the corresponding first side surface 21 of the suction collet 2, the first side wall 31 can hold both ends in the X-direction of the suction collet 2 appropriately in a state where the second side walls 32 are not provided. Since the both ends in the X-direction of the suction collet 2 are held appropriately in the state where the second side walls 32 are not provided, bending of the suction surface 23 caused by fitting of the suction collet 2 into the collet holder 3 can be suppressed. Accordingly, suction leakage of the semiconductor chip C can be reduced appropriately.

FIG. 17 is a diagram illustrating the bending amount of the suction surface 23 of the suction collet 2 in the transfer head 1 according to a working example of the fifth embodiment. In the fifth embodiment, bending of the suction surface 23 occurs in a direction in which the center of the suction surface 23 is recessed due to absence of the second side walls 32. Therefore, the maximum bending amount is defined as the minimum value of the height of the suction surface 23 in the fifth embodiment, differently from the embodiments described above. For example, as illustrated in FIG. 17, according to the fifth embodiment, the maximum bending amount that is the minimum value of the height of the suction surface 23 can be suppressed to δ μm or less because the width W1h of each first side wall 31 is equal to or larger than the width W1c of each first side surface 21.

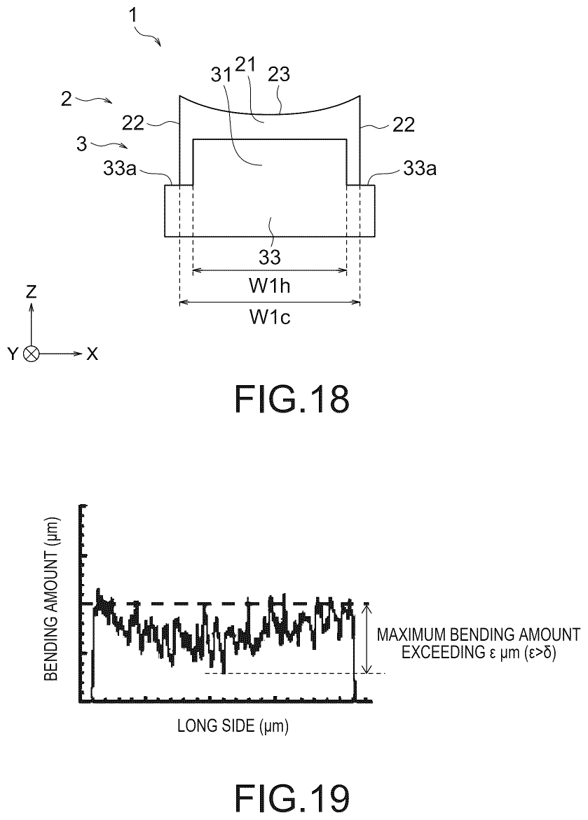

FIG. 18 is a front view illustrating an example of a configuration of the transfer head 1 according to another comparative example. FIG. 19 is a diagram illustrating the bending amount of the suction surface 23 of the suction collet 2 in the transfer head 1 according to the comparative example. Meanwhile, in the example illustrated in FIG. 18, the width W1h of each first side wall 31 is smaller than the width W1c of each first side surface 21. Since the width W1h of each first side wall 31 is smaller than the width W1c of each first side surface 21, the first side walls 31 cannot be in contact with both ends of the suction collet 2 in the X-direction. Therefore, it is difficult for the first side walls 31 to appropriately hold the both ends of the suction collet 2 in the X-direction. Since it is difficult to hold the both ends of the suction collet 2, deformation occurs in such a manner that the both ends of the suction collet 2 protrude upward. Thus, in the example illustrated in FIG. 18, the suction surface 23 bends in such a manner that the height at the center is low and the heights at the both ends in the X-direction are high. For example, as illustrated in FIG. 19, the maximum bending amount of the transfer head 1 illustrated in FIG. 18 exceeds ε μm (ε>δ).

In FIGS. 14 to 16, there has been described an example of the suction collet 2 in which the suction surface 23 has a rectangular shape. Meanwhile, similarly to FIG. 13, the suction surface 23 may have a square shape also in the fifth embodiment.

According to the fifth embodiment, even in a case where second side walls are not provided, bending of the suction surface 23 can be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

### Appendix

(1) An electronic component transfer device comprising:
   a collet including a suction surface that has a quadrilateral shape with four right angles having a first side extending in a first direction and a second side extending in a second direction crossing the first direction in plan view and that is configured to hold an electronic component by sucking the electronic component, a first side surface arranged along the first direction and crossing the suction surface, and a second side surface arranged along the second direction and crossing the suction surface; and
   a holder including a first side wall in contact with the first side surface and having a first height and a second side wall in contact with the second side surface and having a second height lower than the first height, and configured to hold the collet.
(2) The electronic component transfer device according to (1), wherein the suction surface is a flat surface crossing the first side surface and the second side surface.
(3) The electronic component transfer device according to (1), wherein as viewed in the second direction, at least an upper-end side portion of the second side surface, which is adjacent to the suction surface, is positioned between an end of the first side wall in the first direction and an inner surface of the second side wall.
(4) The electronic component transfer device according to (2), wherein the second side surface is a flat surface along an inner surface of the second side wall.
(5) The electronic component transfer device according to (1), wherein the second height is equal to or less than ½ of the first height.
(6) The electronic component transfer device according to (5), wherein the second height is equal to or less than ⅓ of the first height.
(7) The electronic component transfer device according to (1), wherein an upper end surface of the second side wall is a horizontal plane, and the second side wall has the second height in its entirety.
(8) The electronic component transfer device according to (1), wherein an upper end surface of the second side wall is an inclined surface, and the second side wall partly has the second height.
(9) The electronic component transfer device according to (8), wherein the inclined surface is inclined in such a manner that a height thereof decreases toward the second side surface.
(10) The electronic component transfer device according to (1), wherein an upper end surface of the second side wall is a stepped surface, and the second side wall partly has the second height.
(11) The electronic component transfer device according to (10), wherein the stepped surface has a step that makes a height on the second side surface side lower.
(12) The electronic component transfer device according to (1), wherein
   a width of the first side wall is shorter than a width of the first side surface in the first direction, and
   a width of the second side wall is shorter than a width of the second side surface in the second direction.
(13) The electronic component transfer device according to (1), wherein
   the quadrilateral shape with four right angles is a rectangular shape,
   the first direction is a long-side direction of the rectangular shape, and
   the second direction is a short-side direction of the rectangular shape.
(14) The electronic component transfer device according to (1), wherein the quadrilateral shape with four right angles is a square shape.
(15) The electronic component transfer device according to (1), wherein the electronic component is a semiconductor chip.
(16) An electronic component transfer device comprising:
   a collet including a suction surface that has a quadrilateral shape with four right angles having a first side extending in a first direction and a second side extending in a second direction crossing the first direction in plan view and that is configured to hold an electronic component by sucking the electronic component, a first side surface arranged along the first direction and crossing the suction surface, and a second side surface arranged along the second direction and crossing the suction surface; and
   a holder configured to hold the collet, wherein
   the holder has a quadrilateral shape with four right angles and includes a first side wall along the first direction, and
   a width of the first side wall is equal to or larger than a width of the first side surface in the first direction.
(17) The electronic component transfer device according to (16), wherein
   the quadrilateral shape with four right angles is a rectangular shape,
   the first direction is a long-side direction of the rectangular shape, and
   the second direction is a short-side direction of the rectangular shape.
(18) The electronic component transfer device according to (16), wherein the quadrilateral shape with four right angles is a square shape.
(19) The electronic component transfer device according to (16), wherein
   the holder further includes a flat-surface portion adjacent to the second side surface, and
   a position of the flat-surface portion in a third direction crossing the first direction and the second direction is same as a position of a lower end of the first side wall in the third direction.
(20) The electronic component transfer device according to (16), wherein the electronic component is a semiconductor chip.
(21) A semiconductor manufacturing apparatus comprising:
   an electronic component holder configured to hold an electronic component;
   a lifter configured to push up the electronic component held by the electronic component holder; and
   an electronic component transfer device configured transfer the electronic component pushed up by the lifter, wherein
   the electronic component transfer device comprises:
   a collet including a suction surface that has a quadrilateral shape with four right angles having a first side extending in a first direction and a second side extending in a second direction crossing the first direction in plan view and that is configured to hold the electronic component by sucking the electronic component, a first side surface arranged along the first direction and crossing the suction surface, and a second side surface arranged along the second direction and crossing the suction surface; and
   a holder including a first side wall in contact with the first side surface and having a first height and a second side wall in contact with the second side surface and having a second height lower than the first height, and configured to hold the collet.
(22) The semiconductor manufacturing apparatus according to (21), wherein the suction surface is a flat surface crossing the first side surface and the second side surface.
(23) The semiconductor manufacturing apparatus according to (21), wherein at least an upper-end side portion of the second side surface, which is adjacent to the suction surface, is positioned between an end of the first side wall in the first direction and an inner surface of the second side wall as viewed in the second direction.
(24) The semiconductor manufacturing apparatus according to (22), wherein the second side surface is a flat surface along an inner surface of the second side wall.
(25) The semiconductor manufacturing apparatus according to (21), wherein the second height is equal to or less than ½ of the first height.
(26) The semiconductor manufacturing apparatus according to (25), wherein the second height is equal to or less than ⅓ of the first height.
(27) The semiconductor manufacturing apparatus according to (21), wherein an upper end surface of the second side wall is a horizontal plane, and the second side wall has the second height in its entirety.
(28) The semiconductor manufacturing apparatus according to (21), wherein an upper end surface of the second side wall is an inclined surface, and the second side wall partly has the second height.
(29) The semiconductor manufacturing apparatus according to (28), wherein the inclined surface is inclined in such a manner that a height thereof decreases toward the second side surface.
(30) The semiconductor manufacturing apparatus according to (21), wherein an upper end surface of the second side wall is a stepped surface, and the second side wall partly has the second height.
(31) The semiconductor manufacturing apparatus according to (30), wherein the stepped surface has a step that makes a height on the second side surface side lower.
(32) The semiconductor manufacturing apparatus according to (21), wherein
   a width of the first side wall is shorter than a width of the first side surface in the first direction, and
   a width of the second side wall is shorter than a width of the second side surface in the second direction.
(33) The semiconductor manufacturing apparatus according to (21), wherein
   the quadrilateral shape with four right angles is a rectangular shape,
   the first direction is a long-side direction of the rectangular shape, and
   the second direction is a short-side direction of the rectangular shape.
(34) The semiconductor manufacturing apparatus according to (21), wherein the quadrilateral shape with four right angles is a square shape.
(35) The semiconductor manufacturing apparatus according to (21), wherein the electronic component is a semiconductor chip.
(36) A semiconductor manufacturing apparatus comprising:
   an electronic component holder configured to hold an electronic component;
   a lifter configured to push up the electronic component held by the electronic component holder; and
   an electronic component transfer device configured to transfer the electronic component pushed up by the lifter, wherein
   the electronic component transfer device comprises:
   a collet including a suction surface that has a quadrilateral shape with four right angles having a first side extending in a first direction and a second side extending in a second direction crossing the first direction in plan view and that is configured to hold the electronic component by sucking the electronic component, a first side surface arranged along the first direction and crossing the suction surface, and a second side surface arranged along the second direction and crossing the suction surface; and
   a holder configured to hold the collet, and wherein
   the holder has a quadrilateral shape with four right angles and includes a first side wall arranged along the first direction, and
   a width of the first side wall is equal to or larger than a width of the first side surface in the first direction.
(37) The semiconductor manufacturing apparatus according to (36), wherein
   the quadrilateral shape with four right angles is a rectangular shape,
   the first direction is a long-side direction of the rectangular shape, and
   the second direction is a short-side direction of the rectangular shape.
(38) The semiconductor manufacturing apparatus according to (36), wherein the quadrilateral shape with four right angles is a square shape.
(39) The semiconductor manufacturing apparatus according to (36), wherein
   the holder further includes a flat-surface portion adjacent to the second side surface, and
   a position of the flat-surface portion in a third direction crossing the first direction and the second direction is same as a position of a lower end of the first side wall in the third direction.
(40) The semiconductor manufacturing apparatus according to (36), wherein the electronic component is a semiconductor chip.
(41) A holder holding a collet, wherein
   the holder has a quadrilateral shape with four right angles and includes a first side wall arranged along a first direction and a second side wall arranged along a second direction crossing the first direction,
   the first side wall has a first width in the first direction and a first height in a third direction crossing the first direction and the second direction, and
   a second side wall has a second width smaller than the first width in the second direction and a second height lower than the first height in the third direction.
(42) The holder according to (41), wherein the second height is equal to or less than ½ of the first height.
(43) The holder according to (42), wherein the second height is equal to or less than ⅓ of the first height.
(44) The holder according to (41), wherein an upper end surface of the second side wall is a horizontal plane, and the second side wall has the second height in its entirety.
(45) The holder according to (41), wherein an upper end surface of the second side wall is an inclined surface, and the second side wall partly has the second height.
(46) The holder according to (45), wherein the inclined surface is inclined in such a manner that a height thereof decreases toward the second side surface.
(47) The holder according to (41), wherein an upper end surface of the second side wall is a stepped surface, and the second side wall partly has the second height.
(48) The holder according to (47), wherein the stepped surface has a step that makes a height on the second side surface side lower.
(49) The holder according to (41), wherein
   the quadrilateral shape with four right angles is a rectangular shape,
   the first direction is a long-side direction of the rectangular shape, and
   the second direction is a short-side direction of the rectangular shape.
(50) The holder according to (41), wherein the quadrilateral shape with four right angles is a square shape.
(51) The holder according to (41), wherein the electronic component is a semiconductor chip.
(52) A holder holding a collet including a suction surface that has a quadrilateral shape with four right angles having a first side extending in a first direction and a second side extending in a second direction crossing the first direction in plan view and that is configured to hold an electronic component by sucking the electronic component, a first side surface arranged along the first direction and crossing the suction surface, and a second side surface arranged along the second direction and crossing the suction surface, wherein
   the holder has a quadrilateral shape with four right angles and includes a first side wall arranged along the first direction, and
   a width of the first side wall is equal to or larger than a width of the first side surface in the first direction.
(53) The holder according to (52), wherein
   the quadrilateral shape with four right angles is a rectangular shape,
   the first direction is a long-side direction of the rectangular shape, and
   the second direction is a short-side direction of the rectangular shape.
(54) The holder according to (52), wherein the quadrilateral shape with four right angles is a square shape.
(55) The holder according to (52), further including a flat-surface portion adjacent to the second side surface, wherein
   a position of the flat-surface portion in a third direction crossing the first direction and the second direction is same as a position of a lower end of the first side wall in the third direction.
(56) The holder according to (52), wherein the electronic component is a semiconductor chip.

What is claimed is:

1. An electronic component transfer device comprising:
a collet including a suction surface that has a quadrilateral shape with four right angles having a first side extending in a first direction and a second side extending in a second direction crossing the first direction in plan view and that is configured to hold an electronic component by sucking the electronic component, a first side surface arranged along the first direction and crossing the suction surface, and a second side surface arranged along the second direction and crossing the suction surface; and
a holder including a first side wall that is in contact with the first side surface and has a first height and a second side wall that is in contact with the second side surface and has a second height lower than the first height, and configured to hold the collet.

2. The device of claim 1, wherein the suction surface is a flat surface crossing the first side surface and the second side surface.

3. The device of claim 1, wherein as viewed in the second direction, at least an upper-end side portion of the second side surface, which is adjacent to the suction surface, is positioned between an end of the first side wall in the first direction and an inner surface of the second side wall.

4. The device of claim 2, wherein the second side surface is a flat surface along an inner surface of the second side wall.

5. The device of claim 1, wherein the second height is equal to or less than ½ of the first height.

6. The device of claim 5, wherein the second height is equal to or less than ⅓ of the first height.

7. The device of claim 1, wherein an upper end surface of the second side wall is a horizontal plane, and the second side wall has the second height in its entirety.

8. The device of claim 1, wherein an upper end surface of the second side wall is an inclined surface, and the second side wall partly has the second height.

9. The device of claim 8, wherein the inclined surface is inclined in such a manner that a height thereof decreases toward the second side surface.

10. The device of claim 1, wherein an upper end surface of the second side wall is a stepped surface, and the second side wall partly has the second height.

11. The device of claim 10, wherein the stepped surface has a step that makes a height on the second side surface side lower.

12. The device of claim 1, wherein
a width of the first side wall is shorter than a width of the first side surface in the first direction, and
a width of the second side wall is shorter than a width of the second side surface in the second direction.

13. The device of claim 1, wherein
the quadrilateral shape with four right angles is a rectangular shape,
the first direction is a long-side direction of the rectangular shape, and
the second direction is a short-side direction of the rectangular shape.

14. The device of claim 1, wherein the quadrilateral shape with four right angles is a square shape.

15. The device of claim 1, wherein the electronic component is a semiconductor chip.

16. A holder holding a collet, wherein
the holder has a quadrilateral shape with four right angles and includes a first side wall arranged along a first direction and a second side wall arranged along a second direction crossing the first direction,
the first side wall has a first width in the first direction and a first height in a third direction crossing the first direction and the second direction, and
the second side wall has a second width smaller than the first width in the second direction and a second height lower than the first height in the third direction.

17. A holder holding a collet that includes a suction surface having a quadrilateral shape with four right angles having a first side extending in a first direction and a second side extending in a second direction crossing the first direction in plan view and configured to hold an electronic component by sucking the electronic component, a first side surface arranged along the first direction and crossing the suction surface, and a second side surface arranged along the second direction and crossing the suction surface, wherein
the holder has a quadrilateral shape with four right angles and includes a first side wall along the first direction, and
a width of the first side wall is equal to or larger than a width of the first side surface in the first direction.

18. The holder of claim 17, wherein
the quadrilateral shape with four right angles is a rectangular shape,
the first direction is a long-side direction of the rectangular shape, and
the second direction is a short-side direction of the rectangular shape.

19. The holder of claim 1, wherein the quadrilateral shape with four right angles is a square shape.

20. The holder of claim 17, further comprising a flat-surface portion adjacent to the second side surface, wherein
a position of the flat-surface portion in a third direction crossing the first direction and the second direction is same as a position of a lower end of the first side wall in the third direction.
